(19) United States
(12) Patent Application Publication
(10) Pub. No.: US 2020/0091462 A1
(43) Pub. Date: Mar. 19, 2020

(54) METHOD OF MANUFACTURE OLED THIN-FILM ENCAPSULATION LAYER, OLED THIN-FILM ENCAPSULATION STRUCTURE AND OLED STRUCTURE

(71) Applicant: Wuhan China Star Optoelectronics Semiconductor Display Technology Co., Ltd., Wuhan, Hubei (CN)

(72) Inventor: Jing HUANG, Wuhan, Hubei (CN)

(21) Appl. No.: 15/747,083

(22) PCT Filed: Nov. 3, 2017
(86) PCT No.: PCT/CN2017/109299

§ 371 Date: Jan. 23, 2018

(30) Foreign Application Priority Data
Oct. 23, 2017 (CN) 201710993392.X

(51) Int. Cl. H01L 51/52; H01L 51/56

(52) U.S. Cl. CPC H01L 51/5256; H01L 2251/301; H01L 51/56

(57) ABSTRACT

A method of manufacture OLED thin-film encapsulation layer, an OLED thin-film encapsulation structure and an OLED structure are provided. The method of manufacture OLED thin-film encapsulation layer comprises following steps. Depositing a first inorganic material layer on a substrate positioning an OLED element, the first inorganic material layer is totally covered the OLED element; Depositing a first organic material layer on the first inorganic material layer by PECVD process; Depositing a second organic material layer on the first organic material layer by IJP process; Depositing a second inorganic material layer on the second organic material layer. The advantageous of this disclosure could decreases thickness of the OLED thin-film encapsulation layer.

### RELATED APPLICATIONS

The present application is a National Phase of International Application Number PCT/CN2017/109299, filed Nov. 3, 2017, and claims the priority of China Application No. 201710993392.X, filed Oct. 23, 2017.

### FIELD OF THE DISCLOSURE

The disclosure relates to a display technical field, and more particularly to a method of manufacture OLED thin-film encapsulation layer, an OLED thin-film encapsulation structure and an OLED structure.

### BACKGROUND

OLED is widely used for solid state lighting and panel display field so that attract attention of academia and industry. The flexible OLED display is a trend of develop for future display technology. Because the organic emitting material is very sensitive for water and oxygen, the most important issue now is that effectively block the destruction of OLED devices by external water and oxygen for ensures long lifetime of the device. Currently, the more mature flexible encapsulation technology which is achieves by the inorganic/organic multiple alternately thin film structure. The majority function of the inorganic layer is to prevent oxygen or water enter to OLED element, and then cause the emitting become dark; the majority function of the organic layer is to buffer stress of the adjacent inorganic layers, at the same time could also made surface of substrate become flatten and encapsulates particle. In currently technology, the inorganic layer usually deposited by Plasma Enhanced Chemical Vapor Deposition (PECVD), Atomic Layer Deposition (ALD) or Physical Vapor Deposition (PVD) and the organic layer usually manufactured by PECVD or Inkjet printing (IJP).

FIG. 1 is a prior art structural schematic view of an organic layer structure made by PECVD process. The inorganic material layer 2 is positioned on the OLED element 1, the organic material layer 3 is deposited on the inorganic material layer by PECVD process. Generally, the organic material layer made by PECVD usually is hexamethyldisiloxane (HMDSO), the advantage of the process is that could encapsulate and fix particle 4 to a relatively thinner thickness, the disadvantage is that the flattened of substrate surface is worse.

FIG. 2 is a prior art structural schematic view of an organic layer structure made by IJP process; the organic material layer 3 is made by IJP process, and so that the flattened of substrate surface is better because the organic material layer made by IJP process which has good high molecular motivation. But the disadvantage is that the organic material layer need to achieve a predetermine thickness such that provide a good encapsulate effect for particle. In the currently technology, if the organic material layer could totally cover the particle by LJP process, the thickness usually need to be 8-10 um so that the thin-film encapsulation layer usually have thicker thickness, and unfavorable development of the ultra-thin OLED panel.

### SUMMARY

A technical problem to be solved by the disclosure is to provide a method of manufacture OLED thin-film encapsulation layer, an OLED thin-film encapsulation structure and an OLED structure, which could make a thinner organic layer such that decreases thickness of the OLED thin-film encapsulation layer.

Furthermore, the disclosure further provides a method of manufacture OLED thin-film encapsulation layer comprises following steps:

depositing a first inorganic material layer on a substrate positioning an OLED element, the first inorganic material layer is totally covered the OLED element;

depositing a first organic material layer on the first inorganic material layer by PECVD process;

depositing a second organic material layer on the first organic material layer by IJP process;

depositing a second inorganic material layer on the second organic material layer.

In an embodiment, the material of the first inorganic material layer and the second inorganic material layer is one of the SiNx, SiOx, SiON and Al2O3, thickness of inorganic material layers are between 0.5-1 μm.

In an embodiment, the first organic material layer is made by hexamethyldisiloxane (HMDSO), and thickness is between 1-4 μm.

In an embodiment, the second organic material layer is made by one of acrylate, hexamethyldisiloxane, polyacrylate, polycarbonate and polystyrene, and thickness is between 2-4 μm.

According to another aspect of the disclosure, the disclosure further provides an OLED thin-film encapsulation device.

a first inorganic material layer covered an OLED element positioned on a substrate.

a first organic material layer deposited on the first inorganic material layer by PECVD process.

a second organic material layer deposited on the first organic material layer by IJP process.

a second inorganic material layer deposited on the second organic material layer.

In an embodiment, the material of the first inorganic material layer and the second inorganic material layer is one of the SiNx, SiOx, SiON and Al2O3, thickness of inorganic material layers are between 0.5-1 μm.

In an embodiment, the first organic material layer is made by hexamethyldisiloxane (HMDSO), and thickness is between 1-4 μm.

In an embodiment, the second organic material layer is made by one of acrylate, hexamethyldisiloxane, polyacrylate, polycarbonate and polystyrene, and thickness is between 2-4 μm.

According to another aspect of the disclosure, the disclosure yet further provides an OLED device comprising a substrate and an OLED element formed on the substrate, wherein, an OLED thin-film encapsulation structure is formed on the OLED element, the OLED thin-film encapsulation structure comprising:

a first inorganic material layer covered the OLED element positioned on a substrate;

a first organic material layer deposited on the first inorganic material layer by PECVD process;

a second organic material layer deposited on the first organic material layer by IJP process; and

a second inorganic material layer deposited on the second organic material layer.

In an embodiment, the material of the first inorganic material layer and the second inorganic material layer is one of the SiNx, SiOx, SiON and Al2O3, thickness of inorganic material layers are between 0.5-1 μm.

In an embodiment, the first organic material layer is made by hexamethyldisiloxane (HMDSO), and thickness is between 1-4 μm.

In an embodiment, the second organic material layer is made by one of acrylate, hexamethyldisiloxane, polyacrylate, polycarbonate and polystyrene, and thickness is between 2-4 μm.

The embodiment of this present invention provides the following advantageous:

The method of manufacture OLED thin-film encapsulation layer, an OLED thin-film encapsulation structure and an OLED structure, combined the PECVD process and IJP process, and preparing a first organic material layer on the first inorganic material layer by PECVD process, and then preparing a second organic material layer on the first organic material layer by IJP process. Which could ensure an excellent flat effect for substrate and encapsulates particle contaminants, but also reduces thickness of organic layer and suitable for developing ultra-thin OLED.

### BRIEF DESCRIPTION OF THE DRAWINGS

Accompanying drawings are for providing further understanding of embodiments of the disclosure. The drawings form a part of the disclosure and are for illustrating the principle of the embodiments of the disclosure along with the literal description. Apparently, the drawings in the description below are merely some embodiments of the disclosure, a person skilled in the art can obtain other drawings according to these drawings without creative efforts. In the figures:

FIG. 1 is a prior art structural schematic view of an organic layer structure made by PECVD process;

FIG. 2 is a prior art structural schematic view of an organic layer structure made by IJP process;

FIG. 3 is a flowchart schematic view of a method of manufacture OLED thin-film encapsulation layer according to an embodiment of the disclosure;

FIG. 4 is a schematic view of structural obtained by Step S10 from FIG. 3;

FIG. 5 is a schematic view of structural obtained by Step S11 from FIG. 3;

FIG. 6 is a schematic view of structural obtained by Step S12 from FIG. 3; and

FIG. 7 is a schematic view of structural obtained by Step S13 from FIG. 3.

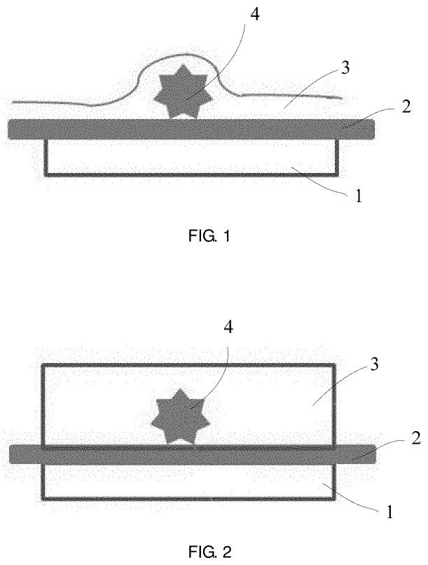

### DETAILED DESCRIPTION OF PREFERRED EMBODIMENTS

The specific structural and functional details disclosed herein are only representative and are intended for describing exemplary embodiments of the disclosure. However, the disclosure can be embodied in many forms of substitution, and should not be interpreted as merely limited to the embodiments described herein.

In the drawings, the thickness of layers and regions are exaggerated for clarity. Like numbers refer to like elements throughout. As used herein the term “and/or” includes any and all combinations of one or more of the associated listed items.

The disclosure will be further described in detail with reference to accompanying drawings and preferred embodiments as follows.

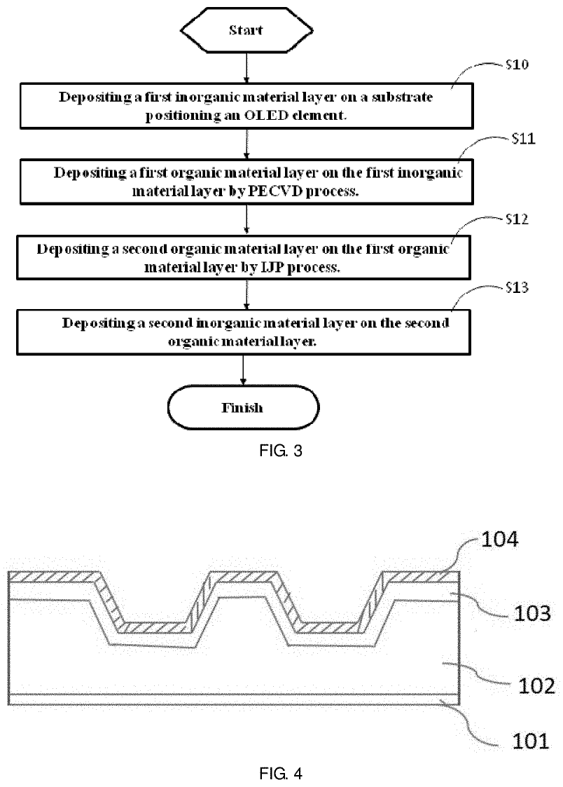

Please refer to the FIG. 3. FIG. 3 is a flowchart schematic view of a method of manufacture OLED thin-film encapsulation layer according to an embodiment of the disclosure. And please also refer to FIG. 4 to FIG. 7, in this embodiment, the method comprising following steps.

Step S10 depositing a first inorganic material layer on a substrate positioning an OLED element thereon; the first inorganic material layer is totally covering the OLED element. It is could be realized that the material of the first inorganic material layer is made by one of the SiNx, SiOx, SiON and Al₂O₃, or other inorganic material which could enhances abilities of anti-water, anti-oxygen. The thickness of the first inorganic material layer is between 0.5-1 μm. The obtaining structure after this step is shown as FIG. 4, wherein, a TFT layer 102 is positioned on the substrate 101, an OLED element layer 103 is positioned on the TFT layer 102, the first inorganic material layer 104 is positioned on the OLED element layer 103. The deposition of those steps could be PECVD, ALD or PVD and so on. The first inorganic material layer 104 could be a single layer or double layers.

Step S11, depositing a first organic material layer on the first inorganic material layer by PECVD process. It is could be realized that for example, the first organic material layer is made by hexamethyldisiloxane (HMDSO), or other material which could be used for buffering the stress when element is bended or curved and covering for particle contaminants. The thickness of the first organic material layer is between 1-4 μm. The obtaining structure after this step is shown as FIG. 5, wherein, the first organic material layer 105 is positioned on the first inorganic material layer 104, and encapsulating the particle contaminant 108. It is could be realized that the particle contaminant 108 is only for illustration. In other embodiment, there could be not existing particle contaminant.

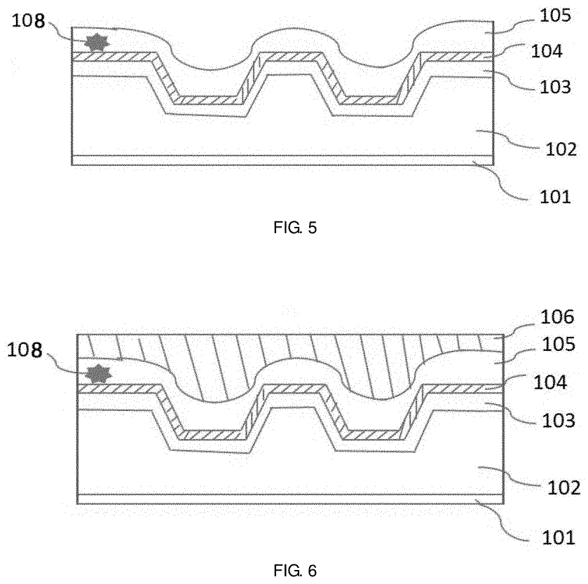

Step S12, depositing a second organic material layer on the first organic material layer by IJP process. Specifically, put the structure obtained by step 11 into IJP equipment and depositing an organic layer. It is could be realized that for example, the second organic material layer is made by one of acrylate, hexamethyldisiloxane, polyacrylate, polycarbonate and polystyrene, or other material which has similar ability. The thickness is between 2-4 μm. Specifically, The obtaining structure after this step is shown as FIG. 6, wherein the second organic material layer 106 is positioned on the first organic material layer 105, and the second organic material layer 106 is obtained by IJP process so that has better flatness.

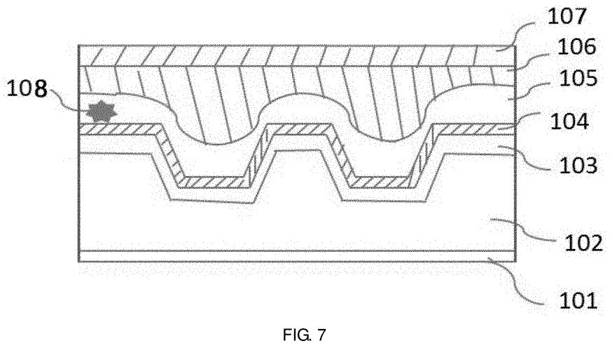

Step S13, depositing a second inorganic material layer on the second organic material layer. It is could be realized that the material of the second inorganic material layer is made by one of the SiNx, SiOx, SiON and Al₂O₃, or other inorganic material which could enhances abilities of anti-water, anti-oxygen. The thickness of the second inorganic material layer is between 0.5-1 μm. The obtaining structure after this step is shown as FIG. 7, wherein, the second inorganic material layer 107 is positioned on the second organic material layer 106. Same, the first inorganic material layer 104 is positioned on the OLED element layer 103. The deposition of those steps could be PECVD, ALD or PVD and so on. The second inorganic material layer 107 could be a single layer or double layers.

According to another aspect of the disclosure, the disclosure further provides an OLED structure. Please refer to FIG. 7, the OLED structure comprises a substrate 101, and an OLED element 103 positioned on the substrate 101, and a thin-film encapsulation structure deposited on the OLED element 103, the thin-film encapsulation structure comprises:

a first inorganic material layer 104 is covering the OLED element 103 positioning on a substrate;

a first organic material layer 105 is deposited on the first inorganic material layer 104 by PECVD process;

a second organic material layer 106 is deposited on the first organic material layer 105 by IJP process;

a second inorganic material layer 107 is deposited on the second organic material layer 106.

The material of the first inorganic material layer 104 and the second inorganic material layer 107 are made by one of the SiNx, SiOx, SiON and Al₂O₃, and thickness of inorganic material layers are between 0.5-1 μm.

The first organic material layer 105 is made by hexamethyldisiloxane (HMDSO), and thickness is between 1-4 μm.

The second organic material layer 106 is made by one of acrylate, hexamethyldisiloxane, polyacrylate, polycarbonate and polystyrene, and thickness is between 2-4 μm.

The more detail could refer to the described above on FIG. 3, here is not repeat again.

It is could be realized that, in a specifically embodiment. Assumed the size of particle contaminants is less than 2 um and according to the method provided in the present invention, which preparing a first organic material layer about 2 um by PECVD process, and then preparing a second organic material layer about 2 um by IJP process. It could using a first organic material layer obtained by PECVD process to fixe and encapsulate particle contaminants, and also using a second organic material layer obtained by IJP process for providing an excellent flat effect. Also the thickness of the organic layer in the thin-film encapsulation layer only about 4 um. Therefore, the invention not only could ensure an excellent flat effect and encapsulates particle contaminants, but also reduces thickness of entirely thin-film encapsulation layer.

The embodiment of this present invention provides the following advantageous:

The method of manufacture OLED thin-film encapsulation layer, an OLED thin-film encapsulation structure and an OLED structure. Combining the PECVD process and IJP process, and preparing a first organic material layer on the first inorganic material layer by PECVD process, and then preparing a second organic material layer on the first organic material layer by IJP process. It could ensure not only an excellent flat effect for substrate and encapsulates particle contaminants, but also reduces thickness of organic layer and suitable for developing ultra-thin OLED.

It should be explained that the relationship terms, such as first and second, etc., in the present application are only used for distinguishing one entity or operation from another entity or operation without requiring or implying any actual relation or sequence existing between these entities or operations. Moreover, the term “include”, “contain” or any other variant means covering instead of exclusively including, so that the process, method, object or device including a series of factors not only includes those factors, but also includes other factors that are not explicitly listed, or further include inherent factors for this process, method, object or device. In a case of no more limitations being provided, the factors defined by the expression “include one . . . ” do not exclude additional identical factors existing in the process, method, object or device which includes the factors.

The above statements are only the specific embodiments of the present application. It should be pointed out that improvements and modification can be made by those ordinary skilled in the art without breaking away from the principle of the present application, also those improvements and modification should be considered as the protection scope of the present application.

What is claimed is:

1. A method of manufacture OLED thin-film encapsulation layer, comprising
depositing a first inorganic material layer on a substrate positioning an OLED element, the first inorganic material layer is totally covered the OLED element;
depositing a first organic material layer on the first inorganic material layer by PECVD process;
depositing a second organic material layer on the first organic material layer by IJP process;
depositing a second inorganic material layer on the second organic material layer.

2. The method of manufacture OLED thin-film encapsulation layer according to claim 1, wherein the material of the first inorganic material layer and the second inorganic material layer is one of the SiNx, SiOx, SiON and Al₂O₃, thickness of inorganic material layers are between 0.5-1 μm.

3. The method of manufacture OLED thin-film encapsulation layer according to claim 1, wherein the first organic material layer is made by hexamethyldisiloxane (HMDSO), and thickness is between 1-4 μm.

4. The method of manufacture OLED thin-film encapsulation layer according to claim 1, wherein the second organic material layer is made by one of acrylate, hexamethyldisiloxane, polyacrylate, polycarbonate and polystyrene, and thickness is between 2-4 μm.

5. The method of manufacture OLED thin-film encapsulation layer according to claim 2, wherein the second organic material layer is made by one of acrylate, hexamethyldisiloxane, polyacrylate, polycarbonate and polystyrene, and thickness is between 2-4 μm.

6. The method of manufacture OLED thin-film encapsulation layer according to claim 3, wherein the second organic material layer is made by one of acrylate, hexamethyldisiloxane, polyacrylate, polycarbonate and polystyrene, and thickness is between 2-4 μm.

7. An OLED thin-film encapsulation device, comprising:
a first inorganic material layer covered an OLED element positioned on a substrate;
a first organic material layer deposited on the first inorganic material layer by PECVD process;
a second organic material layer deposited on the first organic material layer by IJP process; and
a second inorganic material layer deposited on the second organic material layer.

8. The OLED thin-film encapsulation device according to claim 7, wherein the material of the first inorganic material layer and the second inorganic material layer is one of the SiNx, SiOx, SiON and Al₂O₃, thickness of inorganic material layers are between 0.5-1 μm.

9. The OLED thin-film encapsulation device according to claim 7, wherein the first organic material layer is made by hexamethyldisiloxane (HMDSO), and thickness is between 1-4 μm.

10. The OLED thin-film encapsulation device according to claim 9, wherein the second organic material layer is made by one of acrylate, hexamethyldisiloxane, polyacrylate, polycarbonate and polystyrene, and thickness is between 2-4 μm.

11. An OLED device comprising a substrate and an OLED element formed on the substrate, wherein, an OLED thin-film encapsulation structure is formed on the OLED element, the OLED thin-film encapsulation structure comprising:
a first inorganic material layer covered the OLED element positioned on a substrate;
a first organic material layer deposited on the first inorganic material layer by PECVD process;
a second organic material layer deposited on the first organic material layer by IJP process; and
a second inorganic material layer deposited on the second organic material layer.

12. The OLED thin-film encapsulation device according to claim 11, wherein the material of the first inorganic material layer and the second inorganic material layer is one of the SiNx, SiOx, SiON and Al₂O₃, thickness of inorganic material layers are between 0.5-1 μm.

13. The OLED thin-film encapsulation device according to claim 12, wherein the first organic material layer is made by hexamethyldisiloxane (HMDSO), and thickness is between 1-4 μm.

14. The OLED thin-film encapsulation device according to claim 11, wherein the second organic material layer is made by one of acrylate, hexamethyldisiloxane, polyacrylate, polycarbonate and polystyrene, and thickness is between 2-4 μm.

15. The OLED thin-film encapsulation device according to claim 12, wherein the second organic material layer is made by one of acrylate, hexamethyldisiloxane, polyacrylate, polycarbonate and polystyrene, and thickness is between 2-4 μm.

16. The OLED thin-film encapsulation device according to claim 13, wherein the second organic material layer is made by one of acrylate, hexamethyldisiloxane, polyacrylate, polycarbonate and polystyrene, and thickness is between 2-4 μm.
